(19) United States
(12) Patent Application Publication
(10) Pub. No.: US 2015/0237730 A1
(43) Pub. Date: Aug. 20, 2015

(54) CONTROL SYSTEM WITH MULTIPLE TERMINAL BOARDS AND METHOD FOR CONNECTING MULTIPLE TERMINAL BOARDS

(71) Applicant: ABB TECHNOLOGY LTD., Zurich (CH)

(72) Inventors: Wei Liu, Hangzhou (CN); Huan Shi, Hangzhou (CN); Jincheng Li, Hangzhou (CN); Haoran Li, Hangzhou (CN); Axel Lohbeck, Hangzhou (CN)

(73) Assignee: ABB TECHNOLOGY LTD., Zurich (CH)

(21) Appl. No.: 14/434,532

(22) PCT Filed: Oct. 23, 2012
(86) PCT No.: PCT/CN2012/083374

§ 371 Date: Apr. 9, 2015

(51) Int. Cl. H05K 1/14; H05K 3/36

(52) U.S. Cl. CPC H05K 1/144; H05K 3/36; H05K 2201/042; H05K 2201/2027; H05K 2201/10242; H05K 2201/1034; H05K 2201/10356

(57) ABSTRACT

A control system may include a plurality of terminal boards. Each of the plurality of terminal boards may at least include a power pin. The definition of the power pin on at least one of the plurality of terminal boards may be different from the definition of the power pin on another one of the plurality of terminal boards. Thus, if the at least one of the plurality of terminal boards is connected to a wrong input/output module, the input/output module will not get a process power supplied via the power pin on the terminal board. Therefore, a wrong input/output signal will not be transferred, and the input/output module will not be damaged even if a higher process voltage is provided by a wrong terminal board.

### FIELD

The present disclosure relates to the technical field of an industrial control system, and in particular to a control system with multiple terminal boards and a method for connecting multiple terminal boards.

### BACKGROUND

This section provides background information related to the present disclosure which is not necessarily prior art.

The industrial control system is now used in almost every industrial area such as oil & gas, chemical, pharmaceutical, paper, mining and metal. The main purpose of the control system is to control a field device automatically and run a process fast, efficiently and precisely. The control system needs an I/O (Input/Output) module to receive/transfer a signal from/to the field device via a field cable. In most industrial environment, a harsh field environment will cause a dirty signal and some engineers practically choose to use a terminal board to be the first filter to clean the signal.

Normally, different types of I/O modules need corresponding different terminal boards to get the signal filtered. In the engineering practice, a wrong combination of the I/O module with the terminal board will cause a wrong I/O signal. Moreover, the I/O module might even be damaged because a wrong terminal board might also provide a higher process voltage.

### SUMMARY

This section provides a general summary of the present disclosure, and is not a comprehensive disclosure of its full scope or all of its features.

Some embodiments of the present disclosure provide a control system comprising a plurality of terminal boards and a method for connecting the plurality of terminal boards on the control system capable of ensuring that an I/O module will not get a process power if a wrong terminal board is connected, thereby preventing a wrong I/O signal from being transferred and the I/O module from being damaged.

A control system may include a plurality of terminal boards with pins arranged in same configuration. Each of the plurality of terminal boards may at least include a power pin. The definition of the power pin on at least one of the plurality of terminal boards may be different from the definition of the power pin on another one of the plurality of terminal boards.

The term “definition” here means the positional relationship of a pin relative to other pins. More specifically, in the above control system, pins on each terminal board may include a power pin and a signal pin (which includes any pin other than the power pin), and the position of the power pin relative to the signal pin on one terminal board may be different from the position of the power pin relative to the signal pin on another terminal board.

A method for connecting a plurality of terminal boards on a control system may include steps as follows. A power pin on each of the plurality of terminal boards may be arranged so that the definition of the power pin on at least one of the plurality of terminal boards is different from the definition of the power pin on another one of the plurality of terminal boards. A plurality of I/O modules corresponding to the plurality of terminal boards may be provided. A power pin on each of the plurality of I/O modules may be arranged so that the definition of the power pin on each of the plurality of I/O modules corresponds to the definition of the power pin on the corresponding one of the plurality of terminal boards. Each of the plurality of I/O modules may be connected to the corresponding one of the plurality of terminal boards via a cable.

The control system and the method for connecting the plurality of terminal boards on the control system according to the present disclosure may cause the definition of the power pin on at least one of the plurality of terminal boards to be different from the definition of the power pin on another one of the plurality of terminal boards. Thus, if the at least one of the plurality of terminal boards is connected to a wrong I/O module, the I/O module will not get a process power supplied via the power pin on the terminal board. Therefore, a wrong I/O signal will not be transferred, and the I/O module will not be damaged even if a higher process voltage is provided by a wrong terminal board.

Further areas of applicability will become apparent from the description provided herein. The description and specific examples in this summary are intended for purposes of illustration only and are not intended to limit the scope of the present disclosure.

### BRIEF DESCRIPTION OF DRAWINGS

The drawings described herein are for illustrative purposes only of selected embodiments and not all possible implementations, and are not intended to limit the scope of the present disclosure. In the drawings:

FIG. 1 is a schematic diagram of a control system comprising a plurality of terminal boards known by the inventors of the present disclosure;

FIG. 2 is a schematic diagram of an example of a control system comprising a plurality of terminal boards according to an embodiment of the present disclosure;

FIG. 3 is a schematic diagram of an example of an I/O module shown in FIG. 2;

FIG. 4 is a schematic diagram of an example of a protection circuit shown in FIG. 3;

FIG. 5 is a schematic diagram of an example of a power detection circuit shown in FIG. 3; and

FIG. 6 is a flow chart of a method for connecting a plurality of terminal boards on a control system according to the embodiment of the present disclosure.

While the present disclosure is susceptible to various modifications and alternative forms, specific embodiments thereof have been shown by way of example in the drawings and are herein described in detail. It should be understood, however, that the description herein of specific embodiments is not intended to limit the present disclosure to the particular forms disclosed, but on the contrary, the intention is to cover all modifications, equivalents, and alternatives falling within the spirit and scope of the present disclosure. Note that corresponding reference numerals indicate corresponding parts throughout the several views of the drawings.

### DESCRIPTION OF EMBODIMENTS

Examples of the present disclosure will now be described more fully with reference to the accompanying drawings. The following description is merely exemplary in nature and is not intended to limit the present disclosure, application, or uses.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

Further, in this specification and the drawings, each of a plurality of structural elements having substantially the same function is distinguished by affixing a different alphabetical letter to the same reference numeral in some cases. For example, a plurality of structural elements having substantially the same function are distinguished like terminal boards 120a, 120b and 120c where necessary. However, when there is no particular need to distinguish between a plurality of structural elements having substantially the same function, they are denoted by the same reference numeral. For example, when there is no particular need to distinguish between the terminal boards 120a, 120b and 120c, they are referred to simply as the terminal boards 120.

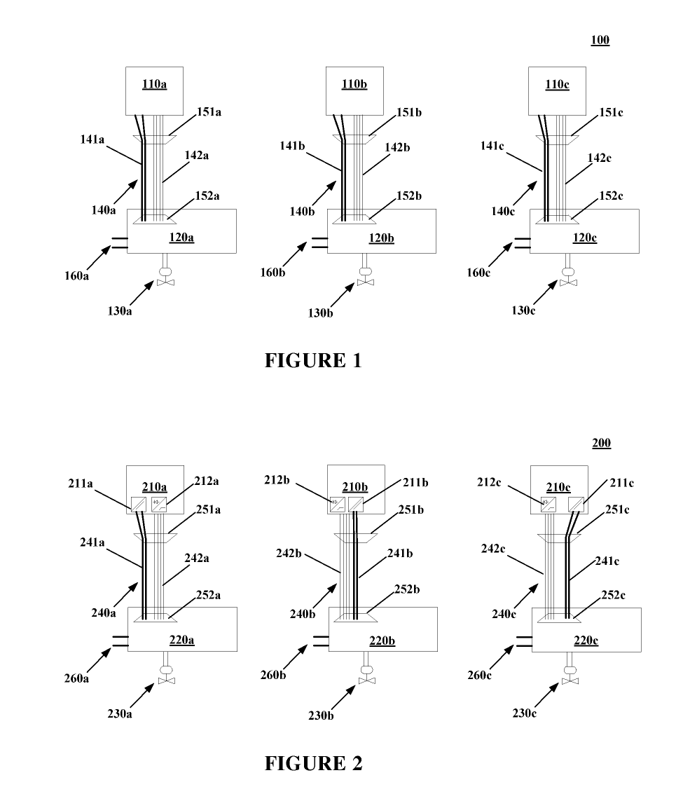

As shown in FIG. 1, a control system 100 known by the inventors of the present disclosure includes three terminal boards 120a, 120b and 120c and three I/O modules 110a, 110b and 110c, which correspond to the three terminal boards 120a, 120b and 120c, respectively. Each terminal board 120 includes a power pin and a signal pin. The I/O module 110a is connected to the terminal board 120a via a DB (D-sub) cable 140a by means of DB connectors 151a and 152a, the I/O module 110b is connected to the terminal board 120b via a DB cable 140b by means of DB connectors 151b and 152b, and the I/O module 110c is connected to the terminal board 120c via a DB cable 140c by means of DB connectors 151c and 152c. Each terminal board 120 is connected to a field device 130.

Each DB cable 140 includes a plurality of leads. A lead for connecting the power pin of the terminal board 120 to the power pin of the corresponding I/O module 110 is referred to as a power lead 141, and a lead for connecting the signal pin of the terminal board 120 to the signal pin of the corresponding I/O module 110 is referred to as a signal lead 142.

It can be seen from FIG. 1 that the definition of the two power pins on the terminal board 120a is same as those on the terminal boards 120b and 120c. That is, the leftmost two pins on each of the terminal boards 120a, 120b and 120c are defined as the power pins.

Further, the definition of the two power pins on each I/O module 110 corresponds to the definition of the two power pins on the corresponding terminal board 120. That is, the leftmost two pins on each of the I/O modules 110a, 110b and 110c are defined as the power pins. Thus, the definition of the two power pins on the I/O module 110a is also same as those on the I/O modules 110b and 110c.

A process power supply 160 may supply a process power to the terminal board 120. Thus, the process power can be transferred from the terminal board 120 to the I/O module 110 via the DB cable 140, particularly the power leads 141.

In a normal condition, after the I/O module 110 is connected to the corresponding terminal board 120 correctly via the DB cable 140, the I/O module 110 may receive a correct signal from the field device 130 via the terminal board 120 and the DB cable 140, or may transfer a correct signal to the field device 130 via the DB cable 140 and the terminal board 120.

In practice, there are different types of I/O modules 110 and therefore corresponding different terminal boards 120. For example, the I/O module 110 may be an analog I/O module, a digital I/O module or the like, and the terminal board 120 may be an analog I/O terminal board, a digital I/O terminal board or the like. If the I/O module 110 is connected to a wrong (i.e. unmatched) terminal board 120 via the DB cable 140, which is very likely to occur since the DB cables 140a, 140b and 140c may be same, the process power is supplied to the I/O module 110 in view of that the definitions of the power pins on the different terminal boards 120 are always same. Thus, the I/O module 110 will be powered, and a wrong I/O signal will be transferred, or even the I/O module 110 will be damaged because the wrong terminal board 120 may provide a higher process voltage.

In view of the circumstances mentioned above, there is provided a control system according to the embodiment of the present disclosure including a plurality of terminal boards. Each of the plurality of terminal boards may at least include a power pin. The definition of the power pin on at least one of the plurality of terminal boards may be different from the definition of the power pin on another one of the plurality of terminal boards.

Specifically, as shown in FIG. 2, a control system 200 according to a specific embodiment of the present disclosure may include three terminal boards 220a, 220b and 220c. Each terminal board 220 at least includes a power pin. In FIG. 2, there are two power pins for each terminal board 220. It will be appreciated by those skilled in the art that the present disclosure has no special limitation to the number of the terminal boards or the power pins.

The power pin of each terminal board 220 is connected with a power lead 241, which will be described later. It can be seen from FIG. 2 that the definition of the two power pins on the terminal board 220a is different from those on the terminal boards 220b and 220c.

Specifically, the leftmost two pins on the terminal board 220a are defined as the power pins, the intermediate two pins on the terminal board 220b are defined as the power pins, and the rightmost two pins on the terminal board 220c are defined as the power pins. To achieve such definition, when an internal circuit of the terminal board 220 is designed, a terminal for transferring the process power in the internal circuit may be arranged so as to be connected to a designated pin in the terminal board 220. For example, the terminals for transferring the process power in the internal circuit of the terminal board 220a are arranged so as to be connected to the leftmost two pins on the terminal board 220a. Likewise, the terminals for transferring the process power in the internal circuit of the terminal board 220b are arranged so as to be connected to the intermediate two pins on the terminal board 220b, and the terminals for transferring the process power in the internal circuit of the terminal board 220c are arranged so as to be connected to the rightmost two pins on the terminal board 220c. Therefore, the power lead 241a, 241b and 241c connected with the power pins on the terminal boards 220a, 220b and 220c, respectively are arranged at different positions.

Thus, if the terminal board 220a is wrongly connected to a module which should be connected to the terminal board 220b, a process power will not be supplied to the module via the power lead 241a since the module shall receive the process power via the power lead 241b. In such a case, a wrong signal will not be transferred by the module. The module herein may be an I/O module to be discussed later, or may be another element such as an isolated gate which will be connected to the terminal board.

According to the preferred embodiment of the present disclosure, the power pin of the terminal board can be arranged so that the definition of the power pin on the terminal board is random. That is, any pins including the leftmost, intermediate, and rightmost pins as mentioned above on the terminal board can be defined as the power pins.

Incidentally, when the remaining terminal boards, if any, are the same type and the wrong connection between them does not need not to be considered, the definitions of the power pins on the remaining terminal boards may also be same.

The control system 200 further includes three I/O modules 210a, 210b and 210c, which correspond to the three terminal boards 220a, 220b and 220c, respectively. Each I/O module 210 also includes two power pins.

The I/O module 210a is connected to the terminal board 220a via a DB cable 240a, the I/O module 210b is connected to the terminal board 220b via a DB cable 240b, and the I/O module 210c is connected to the terminal board 220c via a DB cable 240c. Each DB cable 240 includes a plurality of leads. It is obvious that other type of cable can also be adopted, to which the present disclosure has no particular limitation.

In FIG. 2, the power pin of the terminal board 220 is connected to the power pin of the corresponding I/O module 210 via the power lead 241, the number of which is two for each DB cable 240.

Further, the definition of the two power pins on each I/O module 210 corresponds to the definition of the two power pins on the corresponding terminal board 220. That is, the leftmost two pins on the I/O module 210a are defined as the power pins, the intermediate two pins on the I/O module 210b are defined as the power pins, and the rightmost two pins on the I/O module 210c are defined as the power pins. Thus, the definition of the two power pins on the I/O module 210a is also different from those on the I/O modules 210b and 210c.

Furthermore, as shown in FIG. 2, each terminal board 220 includes four signal pins, and each I/O module 210 also includes four signal pins correspondingly. The signal pin of the terminal board 220 is connected to the signal pin of the corresponding I/O module 210 via a signal lead 242, the number of which is four for each DB cable 240.

Additionally, it is noted that the definition of the four signal pins on each I/O module 210 corresponds to the definition of the four signal pins on the corresponding terminal board 220.

A process power supply 260 may supply a process power to the terminal board 220. After the DB cable 240 is connected with the terminal board 220 by means of a DB connector 252, and the DB cable 240 is connected with the I/O module 210 by means of a DB connector 251, the power pins of the I/O module 210 are connected to the power pins of the corresponding terminal board 220 via the power leads 241, and the signal pins of the I/O module 210 is connected to the signal pins of the corresponding terminal board 220 via the signal leads 242. Thus, the process power can be transferred from the terminal board 220 to the I/O module 210 via the DB cable 240, particularly the power leads 241.

Each terminal board 220 is connected to a field device 230. In a normal condition, after the I/O module 210 is connected to the corresponding terminal board 220 correctly via the DB cable 240, the I/O module 210 may receive a correct signal from the field device 230 via the terminal board 220 and the DB cable 240, or may transfer a correct signal to the field device 230 via the DB cable 240 and the terminal board 220.

According to the embodiment of the present disclosure, even if the I/O module 210 is connected to a wrong terminal board 220 via the DB cable 240, the process power will not be supplied to the I/O module 210 in view of the different definitions of the power pins on the different terminal boards 220. Thus, the I/O module 210 will not be powered, and a wrong I/O signal will not be transferred. Further, the I/O module 210 will not be damaged even if the wrong terminal board 220 provides a higher process voltage.

To explain this point in detail, two critical cases are considered as follows.

In the first case, with reference to FIG. 1, it is assumed that an analog output module 110 is wrongly connected to a digital output terminal board 120. The analog output module 110 is designed to send an analog signal within 0 to 20 mA, and the digital output terminal board 120 is designed to connect to a relay and/or switch 130 to provide an ON/OFF digital signal. In a common structure as shown in FIG. 1, the process power supply 160 will supply the process power to the analog output module 110 via the digital output terminal board 120 and the DB cable 140. Therefore, the analog output module 110 starts to send the current analog signal to the digital output terminal board 120 via the DB cable 140. Since the analog output module 110 and the digital output terminal board 120 are unmatched, the switch 130 will not operate properly. Under such condition, a correct digital signal will never be delivered to the field.

In the second case, with reference to FIG. 1, it is assumed that a digital output module 110 is wrongly connected to a digital input terminal board 120. The digital output module 110 is designed to send an ON/OFF signal to the field, and the digital input terminal board 120 is designed to receive an ON/OFF signal from field Likewise, in the common structure as shown in FIG. 1, the process power supply 160 will supply the process power to the digital output module 110 via the digital input terminal board 120 and the DB cable 140. In some circumstance, a digital input signal transferred by the digital input terminal board 120 will carry a high voltage signal such as 24/48 VDC or even 220 VAC. If this kind of digital input signal is sent to the wrongly connected digital output module 110, the digital output module 110 will be damaged in a short time.

In contrast, the two critical cases as mentioned above are further considered under the circumstance of the present disclosure.

In the first case, with reference to FIG. 2, it is assumed that an analog output module 210a is wrongly connected to a digital output terminal board 220b. The analog output module 210a is designed to send an analog signal within 0 to 20 mA, and the digital output terminal board 220b is designed to connect to a relay and/or switch 230b to provide an ON/OFF digital signal. In such case, the two power pins locating at an intermediate part on the digital output terminal board 220b are connected to two signal pins on the analog output module 210a via the DB cable, while the two power pins locating at the leftmost side on the analog output module 210a are connected to two signal pins on the digital output terminal board 220b via the DB cable. In other words, the two power pins locating at the intermediate part on the digital output terminal board 220b can not be connected to the two power pins locating at the leftmost side on the analog output module 210a. Thus, no process power can be supplied from the process supply power 260b to the analog output module 210a via the digital output terminal board 220b and the DB cable 240b. Therefore, the analog output module 210a will not send the current analog signal to the digital output terminal board 220b via the DB cable 240b.

In the second case, with reference to FIG. 2, it is assumed that a digital output module 210b is wrongly connected to a digital input terminal board 220c. The digital output module 210b is designed to send an ON/OFF signal to the field, and the digital input terminal board 220c is designed to receive an ON/OFF signal from field. A digital input signal transferred by the digital input terminal board 220c will carry a high voltage signal such as 24/48 VDC or even 220 VAC. In such case, the two power pins locating at the rightmost side on the digital input terminal board 220c are connected to two idle pins (or other pins except for the power pins) on the digital output module 210b via the DB cable, while the two power pins locating at an intermediate part on the digital output module 210b are connected to two idle pins (or other pins except for the power pins) on the digital input terminal board 220c via the DB cable. In other words, the two power pins locating at the rightmost side on the digital input terminal board 220c can not be connected to the two power pins locating at the intermediate part on the digital output module 210b. Thus, no process power can be supplied from the process supply power 260c to the digital output module 210b via the digital input terminal board 220c and the DB cable 240c. Therefore, the digital output module 210b may be prevented from being damaged.

Further, each I/O module 210 may be provided with a power detection circuit 211 at the power pins. The power detection circuit 211 can be used to detect the process power transmitted via the power pins of the terminal board 220. Furthermore, each I/O module 210 may also be provided with a protection circuit 212 at the signal pins. The protection circuit 212 can be used to prevent the I/O module 210 from being damaged in a case that the signal pin of the I/O module 210 is wrongly connected to the power pin of the terminal board 220.

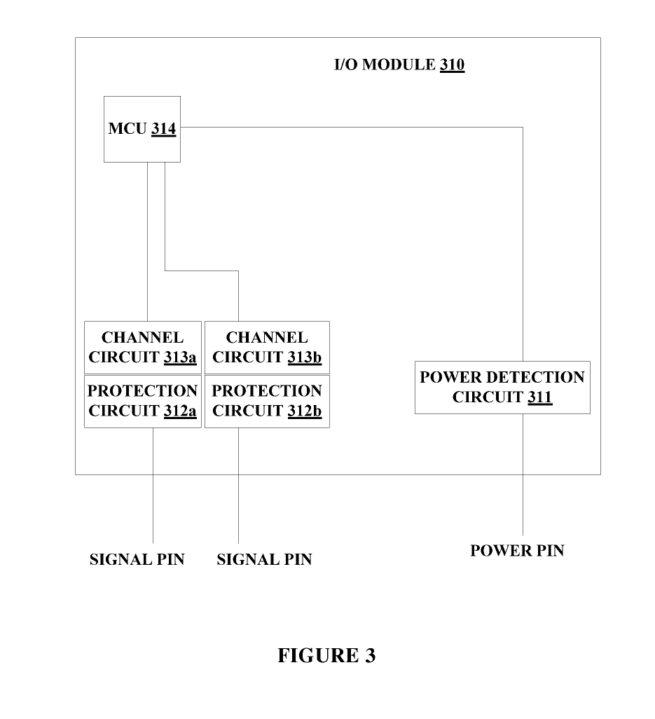

Particularly, as shown in FIG. 3, an I/O module 310 according to a specific embodiment of the present disclosure may include a MCU (Master Control Unit) 314, channel circuits 313a and 313b, protection circuits 312a and 312b, and a power detection circuit 311. The protection circuits 312a and 312b are designed to be connected with the signal pins, and the power detection circuit 311 is designed to be connected with the power pin.

When the I/O module 310 is connected to a corresponding terminal board properly via a cable, the power pin of the I/O module 310 is connected to the power pin of the corresponding terminal board, and the signal pin of the I/O module 310 is connected to the signal pin of the corresponding terminal board.

In such case, a process power will be supplied from the power pin on the corresponding terminal board to the power pin on the I/O module 310 via the cable. Thus, the power detection circuit 311 will detect the process power and then send a corresponding signal to the MCU 314. Base upon the signal sent by the power detection circuit 311, the MCU 314 may cause the I/O module 310 to operate properly.

Further, a signal will be transmitted from the signal pin on the corresponding terminal board to the signal pin on the I/O module 310 via the cable, or vice versa. The signal may arrive to the MCU 314 through the protection circuit 312 and the channel circuit 313, or may be sent by the MCU 314 through the channel circuit 313 and the protection circuit 312. That is, the protection circuit 312 will not influence the performance of the I/O module 310 if the I/O module 310 is connected to the corresponding terminal board properly.

On the other hand, when the I/O module 310 is connected to a wrong terminal board, the power pin of the I/O module 310 will not be connected to the power pin of the wrong terminal board, and some of the signal pins of the I/O module 310 may be connected to the power pin of the wrong terminal board.

In such case, the process power can not be supplied from the power pin on the wrong terminal board to the power pin on the I/O module 310 via the cable. Thus, the power detection circuit 311 will not detect the process power. Thus, the MCU 314 may cause the I/O module 310 not to operate.

Further, the process power may be supplied from the power pin on the wrong terminal board to the signal pin on the I/O module 310 via the cable. At this time, the protection circuit 312 at the signal pin will function so that the process power can not damage the channel circuit 313 and therefore the I/O module 310.

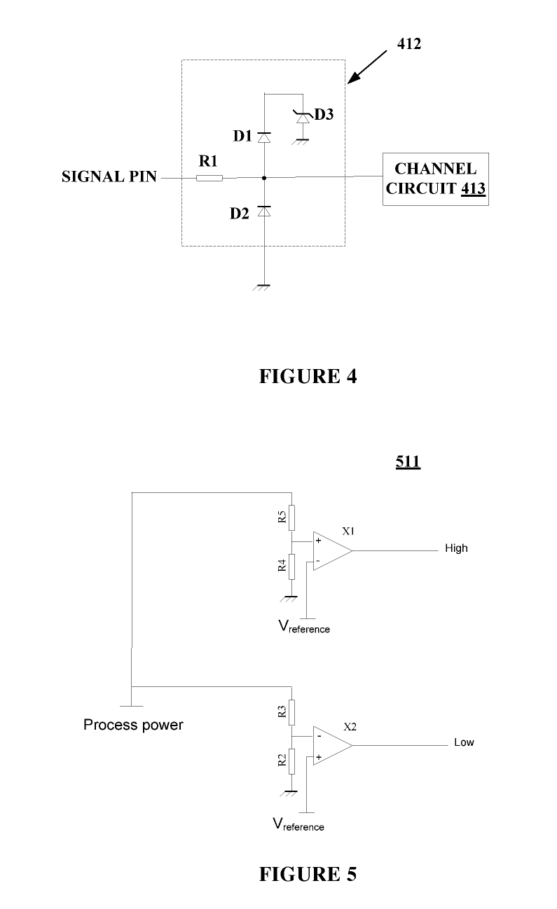

FIG. 4 shows an example of the protection circuit shown in FIG. 3. As shown in FIG. 4, the protection circuit 412 includes a resistor R1 and diodes D1, D2, and D3. An anode of the diode D3 is grounded, a cathode of the diode D3 is connected to a cathode of the diode D1, an anode of the diode D1 is connected to a cathode of the diode D2, and an anode of the diode D2 is grounded. One terminal of the resistor R1 is connected to a signal pin, and the other terminal of the resistor R1 is connected to a node connecting the anode of the diode D1 and the cathode of the diode D2.

With the protection circuit 412 shown in FIG. 4, the voltage of any signal provided to the channel circuit 413 will be limited to a range from 0 to a breakdown voltage for the diode D3. Thus, when a process power with a high voltage which exceeds the range from 0 to the breakdown voltage for the diode D3 is supplied to the signal pin on the I/O module, the process power will not be supplied to the channel circuit 413, and therefore will not damage the channel circuit 413.

Note that the protection circuit 412 shown in FIG. 4 is only for the purpose of illustration, and the present disclosure is not limited thereto. For example, the resistor R1 in FIG. 4 may be replaced with a fuse. Thus, if the process power with the high voltage is supplied, the fuse will be molten and broken. As such, the process power will not be supplied to the channel circuit 413, and therefore will not damage the channel circuit 413.

An example of the power detection circuit shown in FIG. 3 is further provided. As shown in FIG. 5, the power detection circuit 511 includes resistors R2, R3, R4, and R5 and op amplifiers X1 and X2. The resistors R2 and R3 constitute a first voltage divider for dividing the voltage of the process power or the like. The resistors R4 and R5 constitute a second voltage divider for dividing the voltage of the process power or the like. The divided voltage of the first voltage divider is input to a negative input terminal of the op amplifier X2, and a positive input terminal of the op amplifier X2 is connected to a reference terminal V_{reference}. The divided voltage of the second voltage divider is input to a positive input terminal of the op amplifier X1, and a negative input terminal of the op amplifier X1 is connected to the reference terminal V_{reference}.

With the power detection circuit 511 shown in FIG. 5, a process power with a proper voltage level may be detected and a signal indicating thereof may be generated.

Likewise, the power detection circuit 511 shown in FIG. 5 is only for the purpose of illustration, and the present disclosure is not limited thereto. For example, at least one of the op amplifiers X1 and X2 may be replaced with an adjustable precision shunt regulator. Then, the divided voltage of the first or second voltage divider may be connected to a reference terminal of the adjustable precision shunt regulator. Thus, the adjustable precision shunt regulator may produce the same signal as that by the op amplifier X1 or X2.

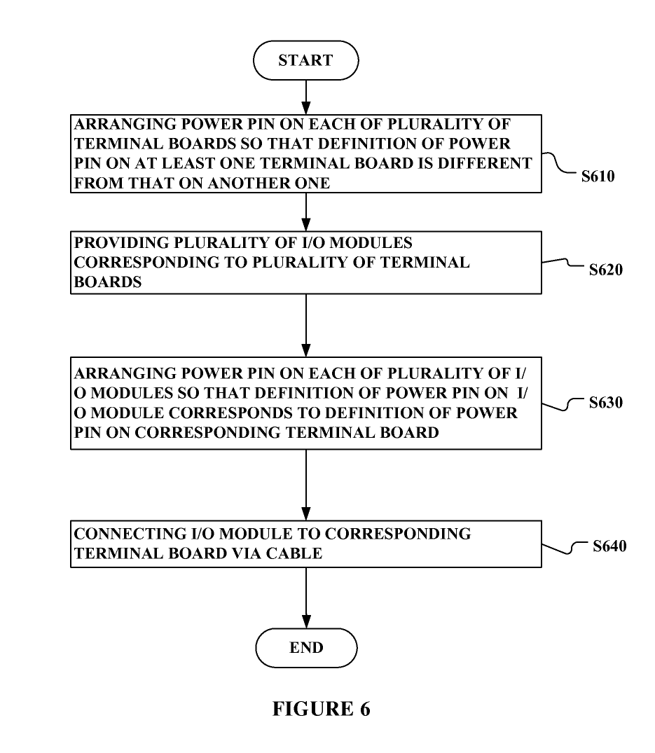

According to another aspect of the present disclosure, there is provided a method for connecting a plurality of terminal boards on a control system, as shown in FIG. 6.

Firstly, in step S610, a power pin on each of the plurality of terminal boards is arranged so that the definition of the power pin on at least one of the plurality of terminal boards is different from the definition of the power pin on another one of the plurality of terminal boards.

Next, in step S620, a plurality of I/O modules corresponding to the plurality of terminal boards are provided.

Next, in step S630, a power pin on each of the plurality of I/O modules is arranged so that the definition of the power pin on each of the plurality of I/O modules corresponds to the definition of the power pin on the corresponding one of the plurality of terminal boards.

At last, in step S640, each of the plurality of I/O modules is connected to the corresponding one of the plurality of terminal boards via a cable.

According to the preferred embodiment of the present disclosure, the power pin on each of the plurality of terminal boards may be arranged such that the definition of the power pin on any one of the plurality of terminal boards is different from the definition of the power pin on the others of the plurality of terminal boards.

According to the preferred embodiment of the present disclosure, the cable may be a DB cable, and the DB cable may be connected with the I/O module and the terminal board, respectively, by means of a DB connector.

According to the preferred embodiment of the present disclosure, a signal pin on each of the plurality of terminal boards and a signal pin on each of the plurality of input/output modules may further be arranged so that the definition of the signal pin on each of the plurality of input/output modules corresponds to the definition of the signal pin on the corresponding one of the plurality of terminal boards.

According to the preferred embodiment of the present disclosure, the power pin of the I/O module may be connected to the power pin of the corresponding terminal board, and the signal pin of the I/O module may be connected to the signal pin of the corresponding terminal board.

According to the preferred embodiment of the present disclosure, a protection circuit may further be provided at the signal pin of the I/O module for preventing the I/O module from being damaged in a case that the signal pin of the I/O module is wrongly connected to the power pin of the terminal board.

According to the preferred embodiment of the present disclosure, a power detection circuit may further be provided at the power pin of the I/O module for detecting the power transmitted via the power pin of the terminal board.

Additionally, the present disclosure further discloses the following solution.

According to an embodiment of the present disclosure, there is provided a terminal board including a power pin, wherein the power pin is arranged so that the definition of the power pin on the terminal board is random.

Preferably, the definition of the power pin on the terminal board of same type is same.

Preferably, the terminal board further includes a signal pin, wherein the power pin and the signal pin are connected with a DB cable by means of a DB connector.

According to an embodiment of the present disclosure, there is provided an input/output module including a power pin, wherein the definition of the power pin on the input/output module corresponds to the definition of a power pin on a terminal board according to the present disclosure.

Preferably, the input/output module is connected to the terminal board via a cable.

Preferably, the cable is a DB cable, and the DB cable is connected with the input/output module and the terminal board, respectively, by means of a DB connector.

Preferably, the input/output module further includes a signal pin.

Preferably, the input/output module further includes a protection circuit at the signal pin of the input/output module for preventing the input/output module from being damaged in a case that the signal pin of the input/output module is wrongly connected to the power pin of the terminal board.

Preferably, the input/output module further includes a power detection circuit at the power pin of the input/output module for detecting the power transmitted via the power pin of the terminal board.

With the technical solution of the present disclosure, the wrong combination of a terminal board and an I/O module will not provide any process power to the I/O module. The field circuit of the I/O module will not be activated. In the mean time, if the system power of the I/O module is connected, a process power detection circuit will detect the process power lost, and then the firmware of I/O module will generate a diagnostic signal to the engineer to inform that the process power is lost.

If the engineer connects a wrong terminal board, the process power might be connected to a signal channel. At this time, the protection circuit in the I/O module is provided to make sure that the process power does not destroy the signal channel.

The present disclosure may provide a control system with a simple and flexible structure. For example, the components of the control system 200 shown in FIG. 2 may be almost same as those of the control system 100 shown in FIG. 1. One of the main differences lies in that the definitions of the power pin on the terminal board and the I/O module are rearranged to be different for each combination of the terminal board and the I/O module. Thus, without changing the standard components, the wrong combination of the terminal board and the I/O module will now cause no problem.

Further, since a control system with a simple and flexible structure is provided, the present disclosure may keep the same manufacture cost and engineering hours with more functionality.

Furthermore, with the technical solution of the present disclosure, the process power will not be supplied to the I/O module unless the right terminal board is connected. Thus, the user will not receive/send any wrong signal from/to the field before the process power is supplied.

The particular embodiments disclosed above are illustrative only, as the disclosure may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the disclosure.

1. A control system comprising a plurality of terminal boards with pins arranged in same configuration, each of the plurality of terminal boards at least including a power pin, wherein the definition of the power pin on at least one of the plurality of terminal boards is different from the definition of the power pin on another one of the plurality of terminal boards.

2. The control system according to claim 1, wherein the definition of the power pin on any one of the plurality of terminal boards is different from the definition of the power pin on the others of the plurality of terminal boards.

3. The control system according to claim 1, further comprising:
a plurality of input/output modules corresponding to the plurality of terminal boards, wherein each of the plurality of input/output modules at least includes a power pin, and the definition of the power pin on each of the plurality of input/output modules corresponds to the definition of the power pin on the corresponding one of the plurality of terminal boards.

4. The control system according to claim 3, wherein each of the plurality of input/output modules is connected to the corresponding one of the plurality of terminal boards via a cable.

5. The control system according to claim 4, wherein the cable is a DB cable, and the DB cable is connected with the input/output module and the terminal board, respectively, by means of a DB connector.

6. The control system according to claim 3, wherein each of the plurality of terminal boards further includes a signal pin, each of the plurality of input/output modules further includes a signal pin, and the definition of the signal pin on each of the plurality of input/output modules corresponds to the definition of the signal pin on the corresponding one of the plurality of terminal boards.

7. The control system according to claim 6, wherein, when each of the plurality of input/output modules is connected to the corresponding one of the plurality of terminal boards via a cable, the power pin of the input/output module is connected to the power pin of the corresponding terminal board, and the signal pin of the input/output module is connected to the signal pin of the corresponding terminal board.

8. The control system according to claim 6, wherein each of the plurality of input/output modules further includes a protection circuit at the signal pin of the input/output module for preventing the input/ output module from being damaged in a case that the signal pin of the input/ output module is wrongly connected to the power pin of the terminal board.

9. The control system according to claim 3, wherein each of the plurality of input/output modules further includes a power detection circuit at the power pin of the input/output module for detecting the power transmitted via the power pin of the terminal board.

10. The control system according to claim 1, wherein each of the plurality of terminal boards is connected to a field device.

11. A method for connecting a plurality of terminal boards on a control system comprising:
arranging a power pin on each of the plurality of terminal boards so that the definition of the power pin on at least one of the plurality of terminal boards is different from the definition of the power pin on another one of the plurality of terminal boards;
providing a plurality of input/output modules corresponding to the plurality of terminal boards;
arranging a power pin on each of the plurality of input/output modules so that the definition of the power pin on each of the plurality of input/output modules corresponds to the definition of the power pin on the corresponding one of the plurality of terminal boards; and
connecting each of the plurality of input/output modules to the corresponding one of the plurality of terminal boards via a cable.

12. The method according to claim 11, wherein the power pin on each of the plurality of terminal boards is arranged such that the definition of the power pin on any one of the plurality of terminal boards is different from the definition of the power pin on the others of the plurality of terminal boards.

13. The method according to claim 11, wherein the cable is a DB cable, and the DB cable is connected with the input/output module and the terminal board, respectively, by means of a DB connector.

14. The method according to claim 11, further comprising:
arranging a signal pin on each of the plurality of terminal boards and a signal pin on each of the plurality of input/output modules so that the definition of the signal pin on each of the plurality of input/output modules corresponds to the definition of the signal pin on the corresponding one of the plurality of terminal boards.

15. The method according to claim 14, wherein the power pin of the input/output module is connected to the power pin of the corresponding terminal board, and the signal pin of the input/output module is connected to the signal pin of the corresponding terminal board.

16. The method according to claim 14, further comprising:
providing a protection circuit at the signal pin of the input/output module for preventing the input/output module from being damaged in a case that the signal pin of the input/output module is wrongly connected to the power pin of the terminal board.

17. The method according to claim 14, further comprising:
providing a power detection circuit at the power pin of the input/output module for detecting the power transmitted via the power pin of the terminal board.

18. The control system according to claim 2, further comprising a plurality of input/output modules corresponding to the plurality of terminal boards, wherein each of the plurality of input/output modules at least includes a power pin, and the definition of the power pin on each of the plurality of input/output modules corresponds to the definition of the power pin on the corresponding one of the plurality of terminal boards.

19. The control system according to claim 8, wherein each of the plurality of input/output modules further includes a power detection circuit at the power pin of the input/output module for detecting the power transmitted via the power pin of the terminal board.

20. The method according to claim 16, further comprising:
providing a power detection circuit at the power pin of the input/output module for detecting the power transmitted via the power pin of the terminal board.
